(19) United States
(12) Patent Application Publication
(10) Pub. No.: US 2025/0329546 A1
(43) Pub. Date: Oct. 23, 2025

(54) LEAD FRAME AND CLIP FRAME FOR MOLDED SEMICONDUCTOR PACKAGES, AND RELATED METHODS OF MANUFACTURING

(71) Applicant: Infineon Technologies AG, Neubiberg (DE)

(72) Inventors: Thorsten Meyer, Regensburg (DE); Thomas Behrens, Wenzenbach (DE); Ludwig Heitzer, Falkenfels (DE); Franz Zollner, Sinzing (DE)

(21) Appl. No.: 18/638,762

(22) Filed: Apr. 18, 2024

(51) Int. Cl. H01L 21/48; H01L 23/00; H01L 23/31; H01L 23/495

(52) U.S. Cl. CPC H01L 21/4828; H01L 23/3107; H01L 23/49562; H01L 23/49575; H01L 24/40; H01L 24/97; H01L 24/48; H01L 2224/40175; H01L 2224/48175; H01L 2224/97

(57) ABSTRACT

A method of producing a clip or lead frame includes: performing a first etching process during which first regions of a metal sheet are not masked and etched to a first depth from a first surface of the metal sheet; and after the first etching process, performing a second etching process during which second regions of the metal sheet are not masked and etched to a second depth from the first surface of the metal sheet, wherein the first regions are not masked during the second etching process such that the first regions are etched to a cumulative depth that corresponds to the first depth plus the second depth, wherein the first regions and the second regions delimit clip or lead frame features. Semiconductor packages that use the clip or lead frame and methods of producing such semiconductor packages are also described.

### BACKGROUND

Many types of semiconductor packages such as half bridges and full bridges for power stages and motor control use metal clips for interconnection of the source pad of a semiconductor die. The metal clips are typically placed one after the other, in a serial manner which is a costly process. The use of a clip frame with multiple metal clips in one frame require bending of the clips prior to use, to compensate for the height difference between the die topside and the lead frame. The bending step is difficult with clip frames and results in large clip height variation.

The restrictions in copper etching/stamping processes of lead frames and clip frames creates a challenge in producing semiconductor packages. Multiple dies are typically integrated in a single power semiconductor package. For example, two vertical power MOSFET (metal-oxide-semiconductor field-effect transistor) dies and a driver are typically integrated in the same half bridge package. One of the two vertical power MOSFETs may be flipped inside the integrated package with a source-down configuration that enables the switching node connection of the half bridge.

Chip embedding is known power semiconductor package technology which offers optimal performance due to a redistribution layer that is used for interconnection. The dies are typically attached to a thick base metal such as a lead frame prior to embedding, but this hinders a flipped chip assembly due to the restrictions in copper etching/stamping processes of the lead frame. In the case of a source-down package configuration, another conventional approach is to use a flip-chip connection for the flipped (source-down) die. This requires copper pillars on the die, causing high bumping cost and providing a partial interconnection only.

Thus, there is a need for an improved process for producing lead frames and clip frames and for semiconductor packages that utilize lead frames and clip frames.

### SUMMARY

According to an embodiment of a method of producing a clip or lead frame, the method comprises: performing a first etching process during which first regions of a metal sheet are not masked and etched to a first depth from a first surface of the metal sheet; and after the first etching process, performing a second etching process during which second regions of the metal sheet are not masked and etched to a second depth from the first surface of the metal sheet, wherein the first regions are not masked during the second etching process such that the first regions are etched to a cumulative depth that corresponds to the first depth plus the second depth, wherein the first regions and the second regions delimit clip or lead frame features.

According to an embodiment of a method of producing semiconductor packages, the method comprises: forming a clip or lead frame by performing a first etching process during which first regions of a metal sheet are not masked and etched to a first depth from a first surface of the metal sheet and after the first etching process, performing a second etching process during which second regions of the metal sheet are not masked and etched to a second depth from the first surface of the metal sheet, wherein the first regions are not masked during the second etching process such that the first regions are etched to a cumulative depth that corresponds to the first depth plus the second depth, wherein the first regions and the second regions delimit one or more features of the clip or lead frame; attaching a plurality of semiconductor dies to the one or more features of the clip or lead frame; and singulating the clip or lead frame with the plurality of semiconductor dies attached thereto into individual semiconductor packages.

According to an embodiment of a semiconductor package, the semiconductor package comprises: a semiconductor die attached to a lead frame at a first side of the semiconductor die; and a metal clip attached to a second side of the semiconductor die opposite the first side, wherein the metal clip has a transition region that extends from a first level above the second side of the semiconductor die to a second level at or below the first side of the semiconductor die, wherein the transition region comprises a first part that protrudes at the first level from a region of the metal clip attached to the second side of the semiconductor die, and a second part that vertically extends from the first part to the second level and has a curved sidewall.

According to another embodiment of a semiconductor package, the semiconductor package comprises: an insulating material; a lead frame embedded in the insulating material; a first semiconductor die embedded in the insulating material and attached to a first metal block of the lead frame at a first side of the first semiconductor die; a second semiconductor die embedded in the insulating material and attached to the lead frame at a first side of the second semiconductor die, wherein the first metal block has a transition region that laterally extends beyond an edge of the first semiconductor die and vertically extends to a level coplanar with or above a second side of the first semiconductor die opposite the first side; and a redistribution structure comprising a first part that connects the transition region of the first metal block to a first electrode at a second side of the second semiconductor die opposite the first side.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A through 1G illustrate partial cross-sectional views of an embodiment of a lead frame/clip frame structuring process.

FIG. 2 illustrates a partial perspective view of a clip frame produced by the lead frame/clip frame structuring process shown in FIGS. 1A through 1G.

FIGS. 3A through 3C illustrate partial cross-sectional views of an embodiment of using the lead frame/clip frame structuring process to produce lead frames.

FIG. 4 illustrates a side perspective view of a semiconductor package, prior to molding, and that includes the clip frame of FIG. 2 and the lead frame of FIG. 3C.

FIGS. 5A through 5C illustrate top perspective views of an embodiment of the lead frame/clip frame structuring process with partial etching on both sides of a clip/lead frame.

FIGS. 6A through 6C illustrate partial top plan views of another embodiment of the lead frame/clip frame structuring process with partial etching on both sides of a clip/lead frame.

FIG. 7A illustrates a cross-sectional view of a semiconductor package.

FIG. 7B illustrates a corresponding top plan view of the semiconductor package, where cross-sectional view of FIG. 7A is taken along the line labelled A-A′ in FIG. 7B.

FIGS. 8A through 8H illustrate an embodiment of a method of producing the semiconductor package shown in FIGS. 7A and 7B.

FIG. 9 illustrates a cross-sectional view of another embodiment of a semiconductor package.

FIG. 10 illustrates a cross-sectional view of another embodiment of a semiconductor package.

FIG. 11 illustrates a cross-sectional view of another embodiment of a semiconductor package.

### DETAILED DESCRIPTION

The embodiments described herein provide methods for producing lead frames and clip frames and semiconductor packages that utilize lead frames and clip frames. The methods include etching of a lead frame or clip frame with a structured etching step of an initial metal (e.g., copper) sheet. This etching step can provide two planes on each side of the lead frame/clip frame. The structuring part of the etching step may be realized by a masking step, e.g., a two-sided lamination of an etch resist, followed by a photo-lithography process, e.g., by laser direct imaging (LDI), mask aligner, stepper, etc. After development of the resist, the etching step is performed and protrusions/recesses are formed. Other areas of the lead frame/clip frame may be covered by an etch resist. In these areas, no further metal removal is performed. In the previously structured areas, which are not covered by a second etch resist, the metal is etched. This way, multiple planes may be generated while maintaining the structuring realized by the first etching step. The highest plane of the lead frame/clip frame is covered by an etching resist first, with other levels/planes being structured sequentially. The structuring process may be used to form elevations/features only on a clip frame, only on a lead frame, or elevations/features on both the clip frame and the lead frame.

Regarding the semiconductor packages described herein, a source-down configuration may be virtually or logically realized by design of an etched lead frame. The lead frame etching process described herein allows to generate a lead frame which offers the die paddle (support) for high-side and low-side power semiconductor dies. The top plane of the lead frame is substantially coplanar with the top side of the dies. The middle plane of the lead frame is the level where the dies are attached. The die paddle of the low-side die has a transition region from the die paddle to the top side of the package. The transition region may be connected by a redistribution structure after embedding the dies in an insulating material such as mold compound. This way, the source pad of the high-side die is connected to the drain pad of the low-side die by the die paddle with the transition region and the redistribution structure. Switch and power/ground connections also may be accounted for as part of the lead frame structuring process such that the required connections may be realized by the redistribution structure. For generation of a half bridge, a driver can also be attached next to the power semiconductor dies, connected by the redistribution structure, or on top of the dies. Some of the semiconductor packages described herein may also utilize a clip frame produced by the lead frame/clip frame structuring process described herein.

Described next, with reference to the figures, are exemplary embodiments of the lead frame/clip frame structuring process and semiconductor packages that include the lead frames and/or clip frames produced by the lead frame/clip frame structuring process.

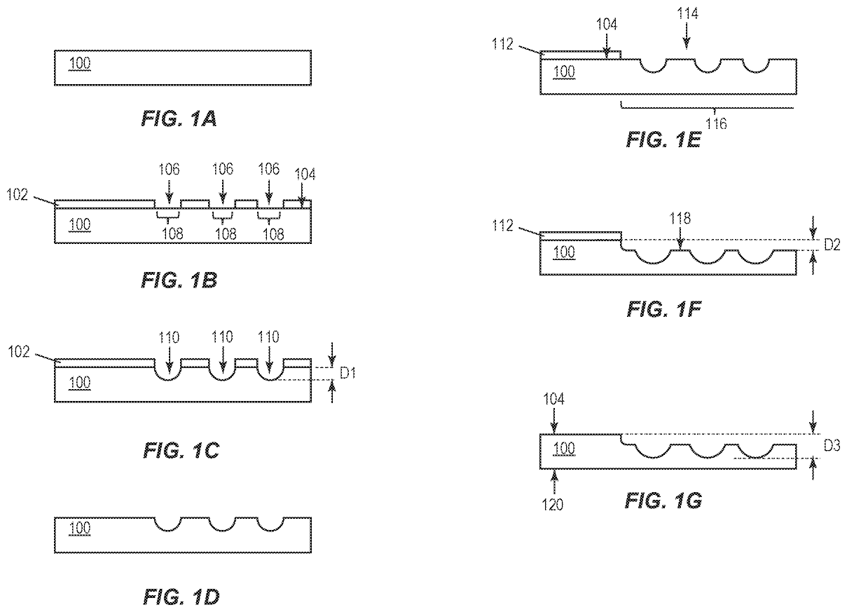

FIGS. 1A through 1G illustrate partial cross-sectional views of an embodiment of the lead frame/clip frame structuring process.

FIG. 1A shows a metal sheet 100. The metal sheet 100 may comprise Cu or another metal or metal alloy suitable for etching and use in semiconductor packages.

FIG. 1B shows a first resist mask 102 formed on a main surface 104 of the metal sheet 100. The main surface 104 may be the front surface or back surface of the metal sheet 100. The first resist mask 102 has openings 106 that define first regions 108 of the metal sheet 100.

FIG. 1C shows a first etching process 110 during which the unmasked first regions 108 of the metal sheet 100 are etched to a first depth D1 from the first surface 104 of the metal sheet 100. The first regions 108 of the metal sheet 100 are etched through the openings 106 in the first resist mask 102 during the first etching process 110.

FIG. 1D shows the metal sheet 100 after completion of the first etching process 110 and after removal of the first resist mask 102.

FIG. 1E shows that after the first etching process, a second resist mask 112 formed on the first surface 104 of the metal sheet 100. The second resist mask 112 has openings 114 that define second regions 116 of the metal sheet 100. The second regions 116 of the metal sheet 100 include the previously etched first regions 108 and additional area of the metal sheet 100. A single opening 114 in the second resist mask 112 and a single second region 116 of the metal sheet 100 are shown in the partial cross-sectional view of FIG. 1E. The second resist mask 112 may include one or more additional openings 114 and one or more corresponding additional second regions 116 of the metal sheet 100 may be unmasked by the additional opening(s) in the second resist mask 112, with these features being out-of-view in FIG. 1E.

FIG. 1F shows a second etching process 118 during which the unmasked second regions 116 of the metal sheet 100 are etched to a second depth D2 from the first surface 104 of the metal sheet 100. Both the second regions 116 and the first regions 108 of the metal sheet 100 are etched through the openings 114 in the second resist mask 112 during the second etching process 118.

FIG. 1G shows the metal sheet 100 after completion of the second etching process 110 and after removal of the first resist mask 102. The first regions 108 of the metal sheet 100 are not masked during the second etching process 118 such that the first regions 108 are etched to a cumulative depth D3 that corresponds to the first depth D1 plus the second depth D2. In the case of accommodating a semiconductor die, the cumulative depth D3 of the first regions 108 should satisfy a clearance requirement for the semiconductor die such that the height difference between the die topside and lead frame is bridged.

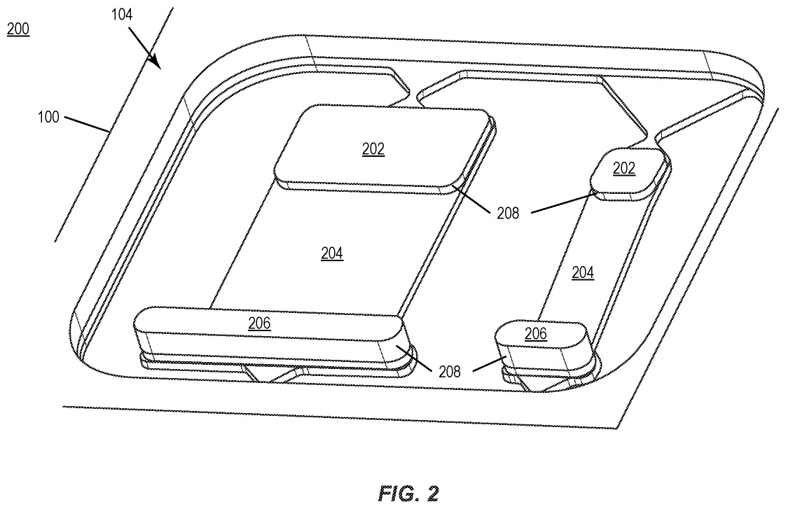

FIG. 2 illustrates a partial perspective view of a clip frame 200 produced by the lead frame/clip frame structuring process shown in FIGS. 1A through 1G. The first regions 108 and the second regions 116 of the metal sheet 100 delimit features 202, 204, 206 of the clip frame 200. Because the clip frame features 202, 204, 206 are defined by etching instead of stamping, the clip frame features 202, 204, 206 have curved sidewalls 208. After completion of both the first and second etching processes 110, 118, a third etching process may be performed during which both the first surface 104 of the metal sheet 100 and the opposite surface 120 are etched without masking to further delimit the clip frame features 202, 204, 206.

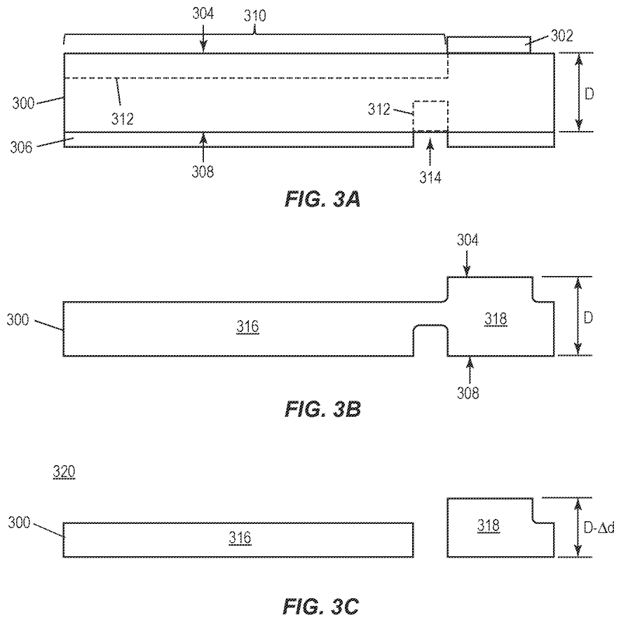

FIGS. 3A through 3C illustrate partial cross-sectional views of an embodiment of using the lead frame/clip frame structuring process to produce lead frames.

FIG. 3A shows a metal sheet 300 with an initial thickness D. The metal sheet 300 may comprise Cu or another metal or metal alloy suitable for etching and use in semiconductor packages. A first resist mask 302 is formed on the front surface 304 of the metal sheet 300 and a second resist mask 306 is formed on the back surface 308 of the metal sheet 300.

The first resist mask 302 has openings 310 that define first regions 312 at the first surface 304 of the metal sheet 300. The second resist mask 306 similarly has one or more openings 314 that at least partly define the first regions 312 at the second surface 308 of the metal sheet 300. A single opening 310 in the first resist mask 302, a single opening 314 in the second resist mask 306, and a single first region 312 of the metal sheet 300 are shown in the partial cross-sectional view of FIG. 3A. One or both resist masks 302, 306 may include one or more additional openings 310, 314 and one or more corresponding additional first regions 312 of the metal sheet 300 may be unmasked by the additional opening(s), with these features being out-of-view in FIG. 3A.

FIG. 3B shows the metal sheet 300 after etching the first regions 312 into the first surface 304 of the metal sheet 300 through the openings 310 in the first resist mask 302 and into the second surface 308 of the metal sheet 300 through the one or more openings 314 in the second resist mask 306. The etching of the metal sheet 300 delimits features 316, 318 of the lead frame being formed from the metal sheet 300.

After the etching of the first regions 312, the first resist mask 302 is removed from the first surface 304 of the metal sheet 300 and the second resist mask 306 is removed from the second surface 308 of the metal sheet 300. The metal sheet 300 retains the initial thickness D in those regions protected by the first and second resist masks 302, 306 during the etching process.

FIG. 3C shows the resulting lead frame 320 after an additional etching process. According to this embodiment, after removing the first and second resist masks 302, 306, the metal sheet 300 is etched from both the front surface 304 and the back surface 308 without masking to further delimit the lead features 316, 318. The additional etching process reduces the thickness of the thickest part of the lead frame 320 from D to D-Ad where Ad corresponds to the amount of metal sheet material removed by the additional etching process.

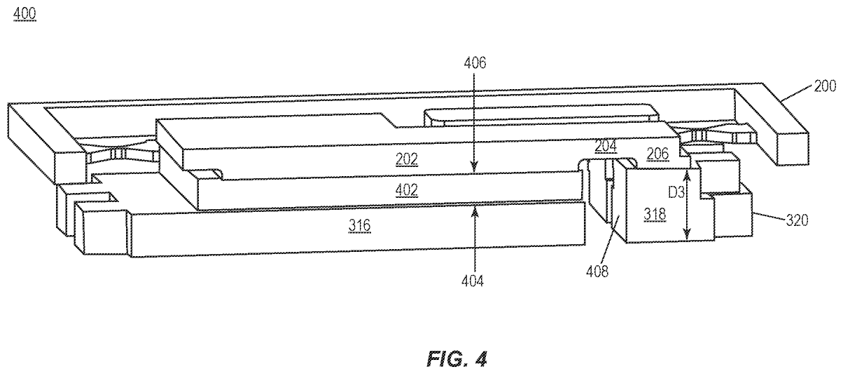

FIG. 4 illustrates a side perspective view of a semiconductor package 400, prior to molding, and that includes the clip frame 200 of FIG. 2 and the lead frame 320 of FIG. 3C. A semiconductor die 402 such as a power transistor die like a Si or SiC power MOSFET die, an IGBT (insulated-gate bipolar transistor) die, GaN HEMT (high-electron mobility transistor) die, etc. is attached to a die paddle feature 316 of the lead frame 320 at a back side 404 of the semiconductor die 402. A die paddle is a part of a lead frame to which one or more semiconductor dies are attached. Another feature 318 of the lead frame 320 provides a vertical connection from the bottom side of the package 400 to the clip frame side.

A first feature 206 of the clip frame 200 connects to the vertical connection feature 318 of the lead frame 320. A second feature 202 of the clip frame 200 is attached to a pad at the top side 406 of the semiconductor die 402. A third feature 204 of the clip frame 200 laterally connects the first and second clip frame features 206, 202. Accordingly, the electrical connection to the front-side pad of the die 402 may be brought down to the bottom side of the package 400 by the clip frame 200 and the vertical connection feature 318 of the lead frame 320. Features 204 and 206 of the clip frame 200 are a protrusion from feature 202 that extends both laterally and vertically. Like the clip frame 200, the lead frame features 316, 318 also have curved sidewalls 408 because the lead frame features 316, 318 are also defined by etching.

As explained above, one or more semiconductor dies 402 are attached to each die paddle 316 of the lead frame 320 during the packaging process. To accommodate a semiconductor die 402, the cumulative depth D3 of the vertical connection feature 318 of the lead frame 320 should satisfy a clearance requirement for the semiconductor die 402 such that the height difference between the die front side 406 and the clip frame 200 is bridged by the lead frame 320.

Alternatively, the clip frame 200 instead may satisfy the clearance requirement for the semiconductor die 402 such that the height difference between the die front side 406 and the lead frame 320 is bridged by the clip frame 200 instead of the lead frame 320. For example, with reference to FIG. 2, the clip frame 200 may have a transition region that extends from a first level above the front side 406 of the semiconductor die 402 to a second level at or below the back side 404 of the semiconductor die 402. The transition region of the clip frame 200 includes a first part 204 that protrudes at the first level from a region 202 of the clip frame 200 attached to the pad at the front side 406 of the semiconductor die 402 and a second part 206 that vertically extends from the first part 204 to the second level and has a curved sidewall 208.

Lead frames and clip frames for discrete or multi-die packages can be complex, a combined bridging by lead frame and clip frame may be provided, e.g., as shown in FIG. 4. The lead frame/clip frame structuring process described herein may be performed on both lead frames and clip frames to achieve recesses and protrusions in common areas. For simplification of the clip frame, partial etching may be used on both sides instead of 3-dimensional etching. An asymmetric etching may be helpful for routing, e.g., to implement fan-out, and structuring.

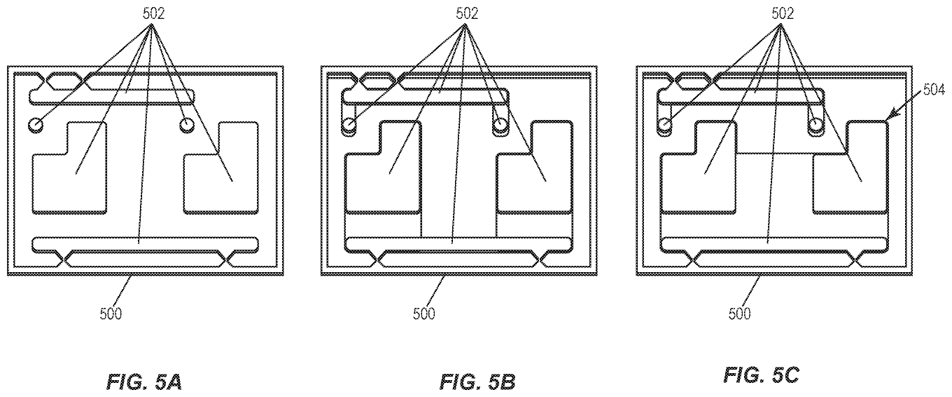

FIGS. 5A through 5C illustrate top perspective views of an embodiment of the lead frame/clip frame structuring process with partial masked etching on both sides of a clip/lead frame individually followed by a double sided, unmasked etching.

FIG. 5A shows a clip/lead frame 500 after a single side half-etching, e.g., in a range of 50 to 100 μm, at the top side with the bottom side masked/protected. The single-sided etching defines features 502 at the front side of the clip/lead frame 500. The features 502 may include die paddles, leads, and vertical connections of a lead frame or leads and vertical connections of a clip frame.

FIG. 5B shows the clip/lead frame 500 after a second single side half-etching, e.g., in a range of 100 to 200 μm, at the top side with the bottom side again masked/protected. The second single-sided etching further defines the features 502 from the front side of the clip/lead frame 500, e.g., by defining regions of different thicknesses.

FIG. 5C shows the clip/lead frame 500 after a double-sided, unmasked etching at both the top and bottom sides. The double-sided etching further defines the features 502 from both the front side and the back side of the clip/lead frame 500. The clip/lead frame features 502 have curved sidewalls 504 due to the etching process.

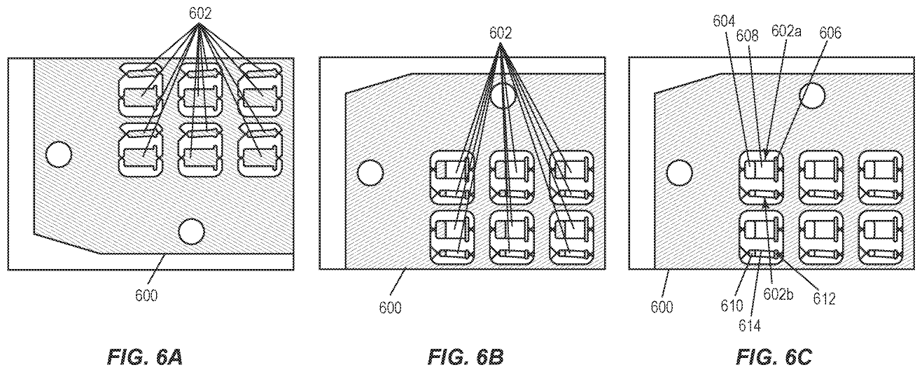

FIGS. 6A through 6C illustrate partial top plan views of another embodiment of the lead frame/clip frame structuring process with partial etching on both sides of a clip/lead frame.

FIG. 6A shows a clip/lead frame 600 after frontside half-etching, e.g., in a range of 50 to 100 μm, with the bottom side masked/protected. The single-sided etching defines features 602 at the front side of the clip/lead frame 500. The features 602 may include die paddles, leads, and vertical connections of a lead frame or leads and vertical connections of a clip frame. The part of the clip/lead frame 600 protected (masked) during the frontside half-etching is crosshatched in FIG. 6A.

FIG. 6B shows the clip/lead frame 600 after a backside half-etching, e.g., in a range of 50 to 100 μm, with the front side masked/protected. The second single-sided etching further defines the features 602 from the back side of the clip/lead frame 500, e.g., by defining regions of different thicknesses. The part of the clip/lead frame 600 protected (masked) during the backside half-etching is crosshatched in FIG. 6B.

FIG. 6C shows the clip/lead frame 600 after a second backside half-etching, e.g., in a range of 50 to 100 μm, with the front side masked/protected. The first and second backside half-etching may be to different depths. The part of the clip/lead frame 600 protected (masked) during the second backside half-etching is crosshatched in FIG. 6C.

The second backside etching further defines the features 602 from the back side of the clip/lead frame 500, e.g., to ensure proper clearance for a semiconductor die. For example, the feature labelled 602a in FIG. 6C may be a first clip for connecting a source pad of a power transistor die to the opposite side of the package that includes the die and the feature labelled 602b in FIG. 6C may be a second clip for connecting a gate pad of the power transistor die to the opposite side of the package. In this example, the first clip 602a includes a first part 604 for contacting the die source pad, a second part 606 for providing the vertical source connection to the opposite side of the package, and a third part 608 for laterally connecting the source pad connection part 604 to the vertical source connection part 606. Similarly, the second clip 60ba includes a first part 610 for contacting the die gate pad, a second part 612 for providing the vertical gate connection to the opposite side of the package, and a third part 614 for laterally connecting the gate pad connection part 610 to the vertical gate connection part 612.

The different parts 604-608, 610-614 of each clip 602a, 602b have different thicknesses to ensure the height of the semiconductor die is properly accommodated. For example, the vertical connection part 606, 612 of each clip 602a, 602b accommodates the entire die thickness. Accordingly, the vertical connection part 606, 612 of each clip 602a, 602b is masked (protected) during each of the etching steps shown in FIGS. 6A through 6C. The lateral connection part 608, 614 is the thinnest part of each clip 602a, 602b and therefore masked (protected) only during the first etching step in FIG. 6A and which initially defines the clip features 602. The die pad connection part 604, 610 of each clip 602a, 602b is masked (protected) during the first and second etching steps shown in FIGS. 6A and 6B but not in the etching step shown in FIG. 6C, to ensure proper contact with the corresponding die pad.

By moving 3-dimensional structuring from a clip frame to a lead frame, the following additional possibilities are enabled. For the clip frame, a simpler clip frame is produced. No tenting (i.e., overarching of etch resist over previously etched recesses) or other complex lamination processes are required for complex lead frame/clip frame structures. For the lead frame, top side etching is performed on a flat assembly and enables integration of other components such as dies with different thicknesses, passive components, sensors or other parts helps to fulfil module requirements. The top side etching also maximizes the clip size for better heat spreading inside the package encapsulation. For bottom side etching, and in combination with mold, glob-top or other isolating materials, re-routing features are enabled which increases creepage distance. Bottom side etching also enables routing in combination with clip frame top-side/bottom-side routing and allows for direct die access, e.g., by removing the clip frame material to allow for die soldering or gluing. The lead frame/clip frame structuring process described herein also allows to generate complex structures by simplifying the process steps.

Described next are embodiments of semiconductor packages that include lead frames and/or clip frames produced by the lead frame/clip frame structuring process described herein.

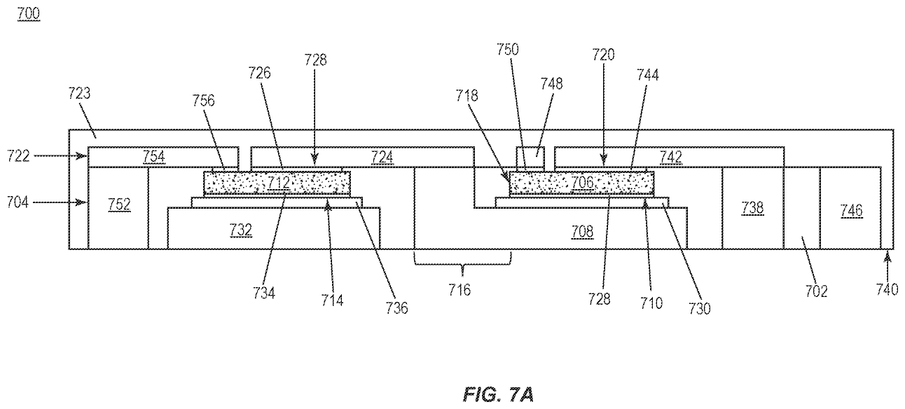

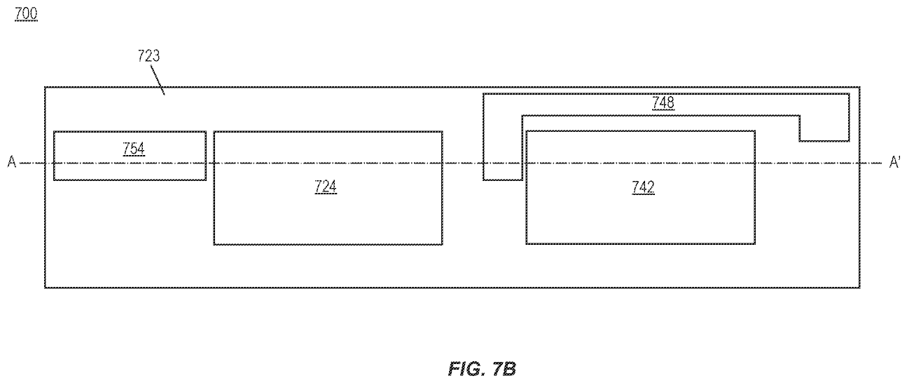

FIG. 7A illustrates a cross-sectional view of a semiconductor package 700. FIG. 7B illustrates a corresponding top plan view of the semiconductor package 700. The cross-sectional view of FIG. 7A is taken along the line labelled A-A′ in FIG. 7B.

The semiconductor package 700 includes an insulating material 702 such as a mold compound, a lead frame 704 embedded in the insulating material 702, and a first semiconductor die 706 embedded in the insulating material 702 and attached to a first metal block 708 of the lead frame 704 at a first side 710 of the first semiconductor die 708. In the case of mold compound as the insulating material 702, the mold compound may be formed by injection molding, transfer molding, compression molding, film assisted molding, etc.

A second semiconductor die 712 embedded in the insulating material 702 is attached to the lead frame 704 at a first side 714 of the second semiconductor die 712. The first metal block 708 has a transition region 716 that laterally extends beyond an edge 718 of the first semiconductor die 706 and vertically extends to a level coplanar with or above the front side 720 of the first semiconductor die 706.

The semiconductor package 700 also includes a metal redistribution structure 722 formed in a second insulating material 723 which may comprise the same or different material as the insulating in which the semiconductor dies 706, 712 and lead frame 704 are embedded. For example, the second insulating material 723 may be a chip (die) embedding material.

The redistribution structure 722 includes a first part 724 that connects the transition region 716 of the first metal block 708 of the lead frame 704 to a first electrode 726 at the front side 728 of the second semiconductor die 712. The redistribution structure 722 may comprise electroplated Cu, for example.

In one embodiment, the first semiconductor die 706 is a low-side switch device of a power electronics circuit such as a half bridge and the second semiconductor die 712 is a high-side switch device of the power electronics circuit. According to this embodiment, the first metal block 708 of the lead frame 704 is attached to a drain electrode 728 at the back side 710 of the first semiconductor die 706 and the first electrode 726 at the front side 728 of the second semiconductor die 712 is a source(S) electrode, such that the drain electrode 728 of the first semiconductor die 706 is electrically connected to the source electrode 726 of the second semiconductor die 712 by the first metal block 708 with the transition region 716 and the first part 724 of the redistribution structure 722. The first metal block 708 of the lead frame 704 may be attached to the drain electrode 728 of the first semiconductor die 706, e.g., by a die attach material 730 such as solder, diffusion solder, an electrically conductive adhesive, etc. A first additional metal block 732 of the lead frame 704 may be attached to the drain electrode 734 at the back side 714 of the second semiconductor die 712, e.g., by a die attach material 736 such as solder, diffusion solder, an electrically conductive adhesive, etc., to provide the high-side input voltage connection.

The low side (e.g., ground) connection to the first semiconductor die 706 is provided by an additional metal block 738 of the lead frame 704 that is separate from the first metal block 708. The additional metal block 738 vertically extends to a level coplanar with or above the front side 720 of the first semiconductor die 706. Both the first metal block 708 and the additional metal block 738 of the lead frame 704 are not covered by the insulating material 702 at the bottom side 740 of the semiconductor package 700. The redistribution structure 722 includes an additional part 742 separate from the first part 724 of the redistribution structure 722 and that connects a source electrode 744 at the front side 720 of the first semiconductor die 706 to the additional metal block 738 of the lead frame 704.

The gate connection to the first semiconductor die 706 also may be provided by an additional metal block 746 of the lead frame 704. The additional metal block 746 vertically extends to a level coplanar with or above the front side 720 of the first semiconductor die 706. The redistribution structure 722 includes an additional part 748 (FIG. 7B) that connects a gate (G) electrode 750 at the front side 720 of the first semiconductor die 706 to the additional metal block 746 of the lead frame 704.

The gate connection to the second semiconductor die 7112 similarly may be provided by an additional metal block 752 of the lead frame 704 that vertically extends to a level coplanar with or above the front side 728 of the second semiconductor die 712. The redistribution structure 722 includes an additional part 754 that connects the additional metal block 752 of the lead frame 704 to a gate electrode 756 at the front side 728 of the second semiconductor die 712. The vertical extension of the transition region 716 of the first metal block 708 and the metal blocks 738, 746, 752 which bring electrical connections down to the back side of the package 700 have a thickness that is greater than or equal to a combined thickness of the die paddles 708, 732 and the semiconductor dies 706, 712.

The lead frame 704 may be produced according to the lead frame/clip frame structuring process described herein. Accordingly, the metal blocks 708, 732, 738, 746, 752 of the lead frame 704, including the transition region 716 of the first metal block 708, may have curved sidewalls, e.g., as shown in the perspective views of FIGS. 2 and 5C.

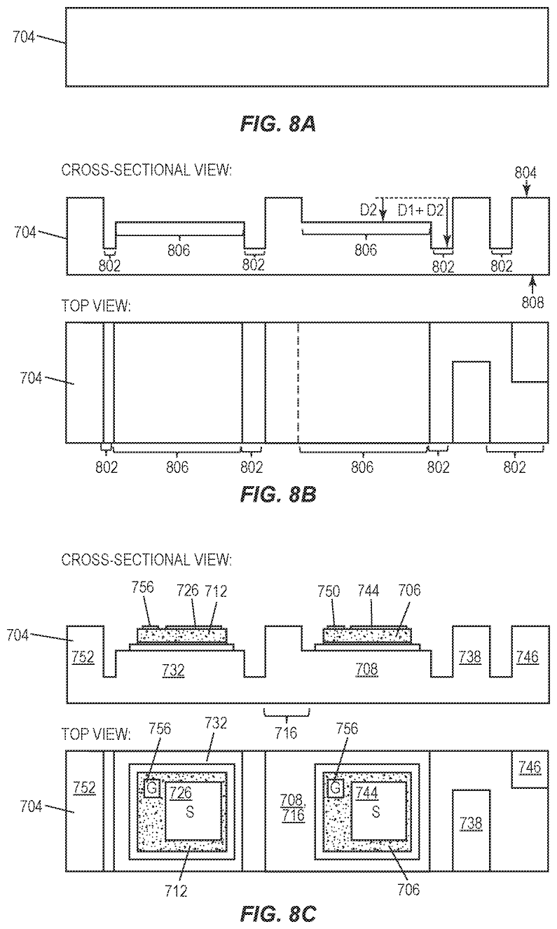

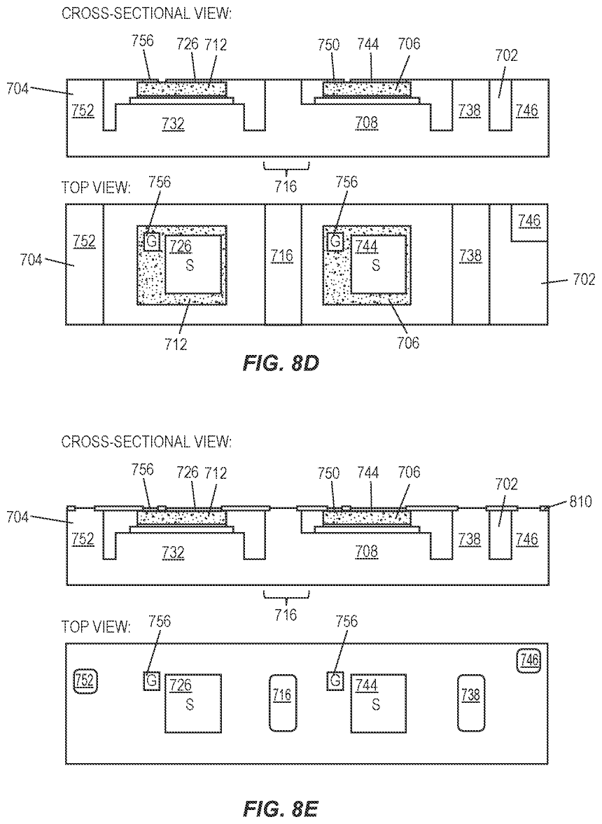

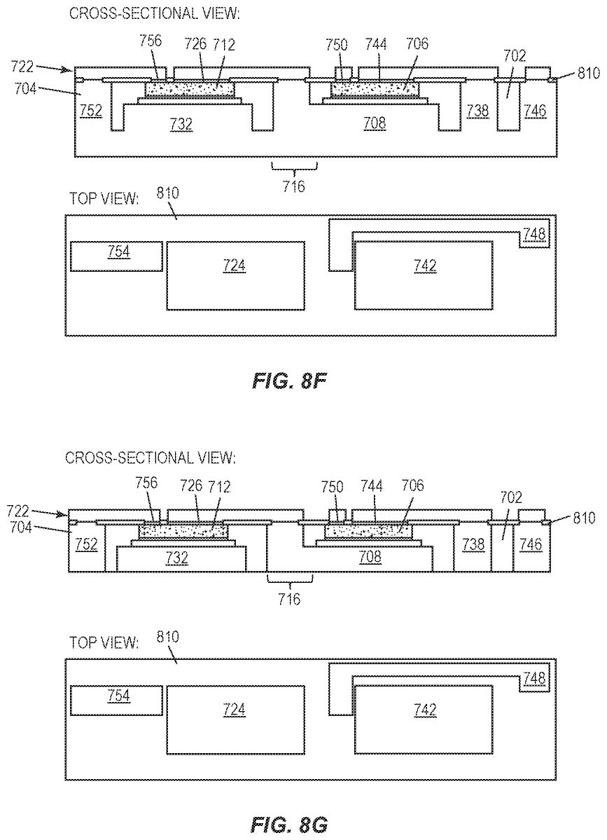

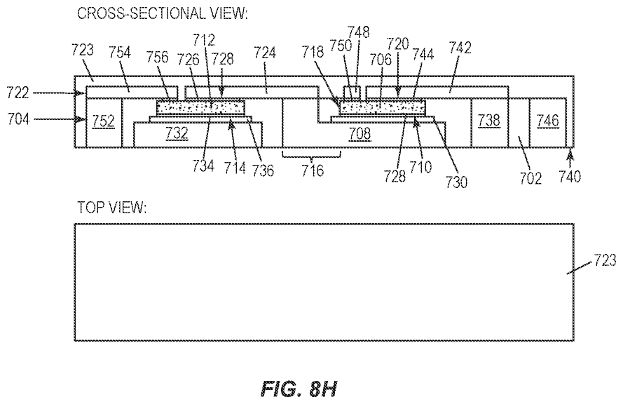

FIGS. 8A through 8H illustrate an embodiment of a method of producing the semiconductor package 700 shown in FIGS. 7A and 7B. FIG. 8A includes a top plan view whereas FIGS. 8B through 8H include both a cross-sectional (upper) view and a top plan (lower) view during corresponding stages of production.

FIG. 8A shows a metal sheet 800 such as a Cu sheet. The metal sheet 800 is subsequently structured by the dual step etching process described herein to form the lead frame 704 shown in FIGS. 7A and 7B.

FIG. 8B shows the metal sheet 800 after a dual step etching process that forms the lead frame 704. During a first etching step, a back surface 808 of the metal sheet 800 is masked while the first regions 802 of the metal sheet 800 are not masked and etched to a first depth D1 from the front surface 804 of the metal sheet 800. During a subsequent second etching process, second regions 806 of the metal sheet 800 are not masked at the front surface 804 and etched to a second depth D2 from the front surface 804 of the metal sheet 800. The first regions 802 also are not masked at the front surface 804 during the second etching process such that the first regions 802 are etched to a cumulative depth that corresponds to the first depth D1 plus the second depth D2. The first regions 802 and the second regions 806 delimit features 708, 716, 732, 738, 746, 725 of the lead frame 704, e.g., such as die paddles, leads, vertical connection regions, etc. As previously described herein, after the first etching process and the second etching process, a third etching process may be performed and during which both the front surface 804 of the metal sheet 800 and the back surface 808 of the metal sheet 802 are etched without masking to further delimit the lead frame features 708, 716, 732, 738, 746, 725.

FIG. 8C shows the lead frame 704 after the first semiconductor die 706 is attached to a first die paddle 708 of the lead frame 704 and the second semiconductor die 712 is attached to a second die paddle 732 of the lead frame 704. The dies 706, 712 may be attached to the lead frame 704 by soldering, diffusion soldering, sintering, gluing, etc.

FIG. 8D shows the lead frame 704 after the open area around the semiconductor dies 706, 712 is filled with the first insulating material 702 such as a mold compound. In one embodiment, a film assisted molding process is used to fill the open space around each die 706, 712 and such that the die topside and lead frame topside are both kept from of mold compound. A cleaning step may be performed after the molding process.

FIG. 8E shows the lead frame 704 after a dielectric 810 such as a solder mask is applied to the topside of the semiconductor dies 706, 712 and lead frame 704, and then structured. The dielectric 810 (areal or structured), curtain coated, laminated, etc. with a potential lithography step for structuring. Depending on the type of material used, the dielectric 810 may be cured.

FIG. 8F shows the lead frame 704 after the electrically conductive redistribution structure 722 is formed. The redistribution structure 722 may be formed by sputtering, electroplating, printing, electroless plating, etc.

FIG. 8G shows the lead frame 704 after etching the entire back side 808 of the lead frame 702. The backside etching may be masked to yield different structuring.

FIG. 8H shows the lead frame 704 after forming the second insulating material 723. In one embodiment, the second insulating material 702 is a mold compound that covers the top side and/or sidewalls of the lead frame 704. The second insulating material 702 may be omitted from the top side of the lead frame 704 if the application calls for double-sided cooling.

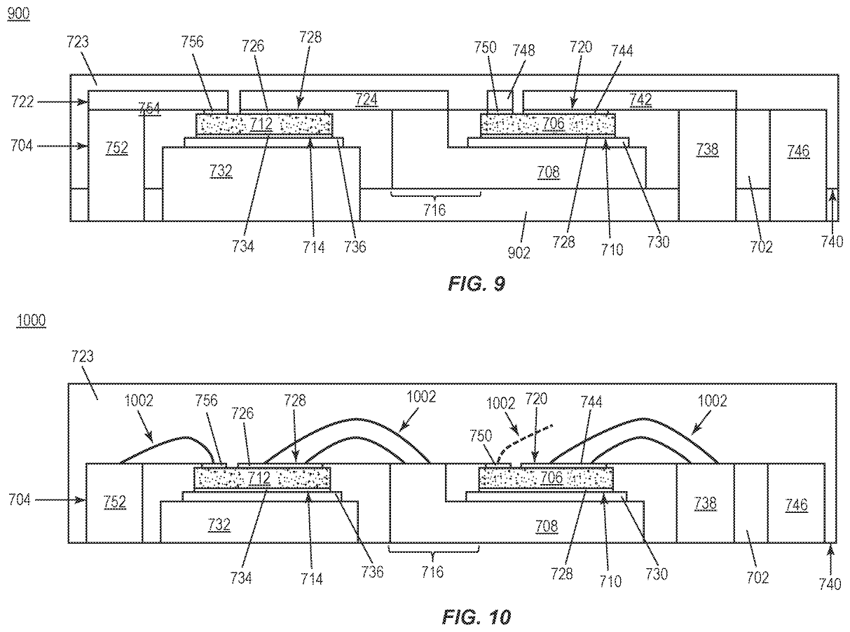

FIG. 9 illustrates a cross-sectional view of another embodiment of a semiconductor package 900. The semiconductor package 900 shown in FIG. 9 is similar to the semiconductor package 700 shown in FIGS. 7A and 7B. In FIG. 9, the bottom side 808 of the lead frame 704 is selectively etched. Any resulting cavities may be filled with an insulating material 902, e.g., by molding, printing, ink jetting, etc.

FIG. 10 illustrates a cross-sectional view of another embodiment of a semiconductor package 1000. The semiconductor package 1000 shown in FIG. 10 is similar to the semiconductor package 700 shown in FIGS. 7A and 7B. In FIG. 10, instead of the redistribution structure 722 is omitted and bond wires 1002 are used to provide the electrical connections between the pads 726, 744, 750, 756 at the front side 720, 728 of the semiconductor dies 706, 712 and the correspond metal blocks 716, 738, 746, 752 of the lead frame 704.

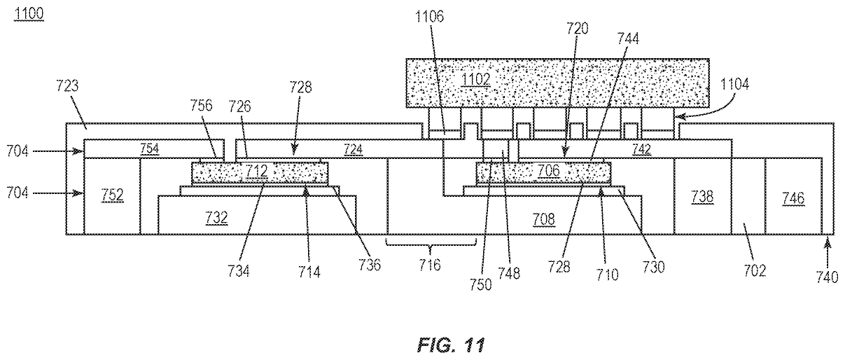

FIG. 11 illustrates a cross-sectional view of a semiconductor package 1100, according to another embodiment. The semiconductor package 1100 shown in FIG. 11 is similar to the semiconductor package 700 shown in FIGS. 7A and 7B. Additionally, the semiconductor package 1100 shown in FIG. 11 also includes a gate driver die 1102 electrically connected to the first semiconductor die 706 and the second semiconductor die 721 by the redistribution structure 722. For example, the gate driver die 1102 may include contact structures 1104 such as solder balls,

Cu pillars, etc. attached to different parts 724, 742, 748 of the gate driver die 1102 by a die attach material 1106 such as solder, diffusion solder, an electrically conductive adhesive, etc. According to the embodiment shown in FIG. 11, the first semiconductor die 706 and the second semiconductor die 712 are each a power transistor die driven by the gate driver die 1102. Other types of dies may be attached to the top side of the package 1100, e.g., such as a controller die, sensor die, etc.

Although the present disclosure is not so limited, the following numbered examples demonstrate one or more aspects of the disclosure.

Example 1. A method of producing a clip or lead frame, the method comprising: performing a first etching process during which first regions of a metal sheet are not masked and etched to a first depth from a first surface of the metal sheet; and after the first etching process, performing a second etching process during which second regions of the metal sheet are not masked and etched to a second depth from the first surface of the metal sheet, wherein the first regions are not masked during the second etching process such that the first regions are etched to a cumulative depth that corresponds to the first depth plus the second depth, wherein the first regions and the second regions delimit clip or lead frame features.

Example 2. The method of example 1, wherein performing the first etching process comprises: forming a resist mask on the first surface of the metal sheet, the resist mask having openings that define the first regions; and etching the first regions through the openings in the resist mask.

Example 3. The method of example 1 or 2, wherein performing the second etching process comprises: forming a resist mask on the first surface of the metal sheet, the resist mask having openings that define the second regions and include the first regions; and etching the second regions and the first regions through the openings in the resist mask.

Example 4. The method of any of examples 1 through 3, further comprising: after the first etching process and the second etching process, performing a third etching process during which both the first surface of the metal sheet and a second surface of the metal sheet opposite the first surface are etched without masking to further delimit the clip or lead frame features.

Example 5. The method of example 1 or 4, wherein performing the first etching process comprises: forming a first resist mask on the first surface of the metal sheet, the first resist mask having openings that define the first regions; etching the first regions through the openings in the first resist mask; and after the etching of the first regions, removing the first resist mask from the first surface of the metal sheet.

Example 6. The method of example 5, wherein performing the second etching process comprises: after the removing of the first resist mask, forming a second resist mask on the first surface of the metal sheet, the second resist mask having openings that define the second regions and include the first regions; etching both the second regions and the first regions through the openings in the second resist mask; and after the etching of both the second regions and the first regions, removing the second resist mask from the first surface of the metal sheet.

Example 7. The method of example 6, further comprising: after the first etching process and the second etching process, performing a third etching process during which both the first surface of the metal sheet and a second surface of the metal sheet opposite the first surface are etched without masking to further delimit the clip or lead frame features.

Example 8. The method of example 1 or 4, wherein performing the first etching process comprises: forming a first resist mask on the first surface of the metal sheet and a second resist mask on a second surface of the metal sheet opposite the first surface, the first resist mask having openings that define the first regions at the first surface of the metal sheet, the second resist mask having one or more openings that at least partly define the first regions at the second surface of the metal sheet; etching the first regions into the first surface of the metal sheet through the openings in the first resist mask and into the second surface of the metal sheet through the one or more openings in the second resist mask; and after the etching of the first regions, removing the first resist mask from the first surface of the metal sheet and the second resist mask from the second surface of the metal sheet.

Example 9. The method of example 8, wherein performing the second etching process comprises: after the removing of the first resist mask and the second resist mask, etching the metal sheet from both the first surface and the second surface without masking to further delimit the clip or lead frame features.

Example 10. The method of any of examples 1 through 9, wherein the cumulative depth of the first regions satisfies a semiconductor die clearance requirement.

Example 11. A method of producing semiconductor packages, the method comprising: forming a clip or lead frame by performing a first etching process during which first regions of a metal sheet are not masked and etched to a first depth from a first surface of the metal sheet and after the first etching process, performing a second etching process during which second regions of the metal sheet are not masked and etched to a second depth from the first surface of the metal sheet, wherein the first regions are not masked during the second etching process such that the first regions are etched to a cumulative depth that corresponds to the first depth plus the second depth, wherein the first regions and the second regions delimit one or more features of the clip or lead frame; attaching a plurality of semiconductor dies to the one or more features of the clip or lead frame; and singulating the clip or lead frame with the plurality of semiconductor dies attached thereto into individual semiconductor packages.

Example 12. The method of example 11, further comprising: after the first etching process and the second etching process, performing a third etching process during which both the first surface of the metal sheet and a second surface of the metal sheet opposite the first surface are etched without masking to further delimit the clip or lead frame features.

Example 13. The method of example 11 or 12, wherein the frame is a clip frame, and wherein the clip frame features include a metal block attached to each semiconductor die and a protrusion from the metal block that extends both laterally and vertically.

Example 14. The method of example 11 or 12, wherein the frame is a lead frame, wherein the lead frame features include a first metal block attached to each semiconductor die and a second metal block separate from the first metal block, wherein a thickness of the second metal block is greater than or equal to a combined thickness of the first metal block and the semiconductor dies.

Example 15. The method of example 11 or 12, wherein the frame is a clip frame, the method further comprising: forming a lead frame by performing a third etching process during which first regions of an additional metal sheet are not masked and etched to a third depth from a first surface of the additional metal sheet and after the third etching process, performing a fourth etching process during which second regions of the additional metal sheet are not masked and etched to a fourth depth from the first surface of the additional metal sheet, wherein the first regions of the additional metal sheet are not masked during the fourth etching process such that the first regions of the additional metal sheet are etched to a cumulative depth that corresponds to the third depth plus the fourth depth, wherein the first regions and the second regions of the additional metal sheet delimit one or more features of the lead frame; and attaching the plurality of semiconductor dies to the one or more features of the lead frame; and singulating both the clip frame and the lead frame with the plurality of semiconductor dies attached thereto into the individual semiconductor packages.

Example 16. A semiconductor package, comprising: a semiconductor die attached to a lead frame at a first side of the semiconductor die; and a metal clip attached to a second side of the semiconductor die opposite the first side, wherein the metal clip has a transition region that extends from a first level above the second side of the semiconductor die to a second level at or below the first side of the semiconductor die, wherein the transition region comprises a first part that protrudes at the first level from a region of the metal clip attached to the second side of the semiconductor die, and a second part that vertically extends from the first part to the second level and has a curved sidewall.

Example 17. A semiconductor package, comprising: an insulating material; a lead frame embedded in the insulating material; a first semiconductor die embedded in the insulating material and attached to a first metal block of the lead frame at a first side of the first semiconductor die; a second semiconductor die embedded in the insulating material and attached to the lead frame at a first side of the second semiconductor die, wherein the first metal block has a transition region that laterally extends beyond an edge of the first semiconductor die and vertically extends to a level coplanar with or above a second side of the first semiconductor die opposite the first side; and a redistribution structure comprising a first part that connects the transition region of the first metal block to a first electrode at a second side of the second semiconductor die opposite the first side.

Example 18. The semiconductor package of example 17, wherein the lead frame comprises an additional metal block separate from the first metal block, wherein the additional metal block vertically extends to a level coplanar with or above the second side of the first semiconductor die, wherein both the first metal block and the additional metal block are not covered by the insulating material at a first side of the semiconductor package, and wherein the redistribution structure comprises an additional part separate from the first part that connects an electrode at the second side of the first semiconductor die to the additional metal block.

Example 19. The semiconductor package of example 18, wherein the second metal block has a curved sidewall.

Example 20. The semiconductor package of any of examples 17 through 19, wherein the transition region of the first metal block has a curved sidewall.

Example 21. The semiconductor package of any of examples 17 through 20, wherein the lead frame comprises an additional metal block that vertically extends to a level coplanar with or above the second side of the second semiconductor die, and wherein the redistribution structure comprises an additional part that connects the additional metal block to a second electrode at the second side of the second semiconductor die.

Example 22. The semiconductor package of example 21, wherein the additional metal block has a curved sidewall.

Example 23. The semiconductor package of any of examples 17 through 22, further comprising: a gate driver die electrically connected to the first semiconductor die and the second semiconductor die, wherein the first semiconductor die and the second semiconductor die are each a power transistor die driven by the gate driver die.

Example 24. The semiconductor package of any of examples 17 through 23, wherein the first semiconductor die is a low-side switch device of a power electronics circuit, and wherein the second semiconductor die is a high-side switch device of the power electronics circuit.

Example 25. The semiconductor package of example 24, wherein the power electronics circuit is a half bridge.

Example 26. The semiconductor package of any of examples 17 through 25, wherein the first metal block is attached to a drain electrode at the first side of the first semiconductor die and the first electrode at the second side of the second semiconductor die is a source electrode, such that the drain electrode of the first semiconductor die is electrically connected to the source electrode of the second semiconductor die by the first metal block with the transition region and the first part of the redistribution structure.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of producing a clip or lead frame, the method comprising:
performing a first etching process during which first regions of a metal sheet are not masked and etched to a first depth from a first surface of the metal sheet; and
after the first etching process, performing a second etching process during which second regions of the metal sheet are not masked and etched to a second depth from the first surface of the metal sheet,
wherein the first regions are not masked during the second etching process such that the first regions are etched to a cumulative depth that corresponds to the first depth plus the second depth,
wherein the first regions and the second regions delimit clip or lead frame features.

2. The method of claim 1, wherein performing the first etching process comprises:
forming a resist mask on the first surface of the metal sheet, the resist mask having openings that define the first regions; and
etching the first regions through the openings in the resist mask.

3. The method of claim 1, wherein performing the second etching process comprises:
forming a resist mask on the first surface of the metal sheet, the resist mask having openings that define the second regions and include the first regions; and
etching the second regions and the first regions through the openings in the resist mask.

4. The method of claim 1, further comprising:
after the first etching process and the second etching process, performing a third etching process during which both the first surface of the metal sheet and a second surface of the metal sheet opposite the first surface are etched without masking to further delimit the clip or lead frame features.

5. The method of claim 1, wherein performing the first etching process comprises:
forming a first resist mask on the first surface of the metal sheet, the first resist mask having openings that define the first regions;
etching the first regions through the openings in the first resist mask; and
after the etching of the first regions, removing the first resist mask from the first surface of the metal sheet.

6. The method of claim 5, wherein performing the second etching process comprises:
after the removing of the first resist mask, forming a second resist mask on the first surface of the metal sheet, the second resist mask having openings that define the second regions and include the first regions;
etching both the second regions and the first regions through the openings in the second resist mask; and
after the etching of both the second regions and the first regions, removing the second resist mask from the first surface of the metal sheet.

7. The method of claim 6, further comprising:
after the first etching process and the second etching process, performing a third etching process during which both the first surface of the metal sheet and a second surface of the metal sheet opposite the first surface are etched without masking to further delimit the clip or lead frame features.

8. The method of claim 1, wherein performing the first etching process comprises:
forming a first resist mask on the first surface of the metal sheet and a second resist mask on a second surface of the metal sheet opposite the first surface, the first resist mask having openings that define the first regions at the first surface of the metal sheet, the second resist mask having one or more openings that at least partly define the first regions at the second surface of the metal sheet;
etching the first regions into the first surface of the metal sheet through the openings in the first resist mask and into the second surface of the metal sheet through the one or more openings in the second resist mask; and
after the etching of the first regions, removing the first resist mask from the first surface of the metal sheet and the second resist mask from the second surface of the metal sheet.

9. The method of claim 8, wherein performing the second etching process comprises:
after the removing of the first resist mask and the second resist mask, etching the metal sheet from both the first surface and the second surface without masking to further delimit the clip or lead frame features.

10. The method of claim 1, wherein the cumulative depth of the first regions satisfies a semiconductor die clearance requirement.

11. A method of producing semiconductor packages, the method comprising:
forming a clip or lead frame by performing a first etching process during which first regions of a metal sheet are not masked and etched to a first depth from a first surface of the metal sheet and after the first etching process, performing a second etching process during which second regions of the metal sheet are not masked and etched to a second depth from the first surface of the metal sheet, wherein the first regions are not masked during the second etching process such that the first regions are etched to a cumulative depth that corresponds to the first depth plus the second depth, wherein the first regions and the second regions delimit one or more features of the clip or lead frame;
attaching a plurality of semiconductor dies to the one or more features of the clip or lead frame; and
singulating the clip or lead frame with the plurality of semiconductor dies attached thereto into individual semiconductor packages.

12. The method of claim 11, further comprising:
after the first etching process and the second etching process, performing a third etching process during which both the first surface of the metal sheet and a second surface of the metal sheet opposite the first surface are etched without masking to further delimit the clip or lead frame features.

13. The method of claim 11, wherein the frame is a clip frame, and wherein the clip frame features include a metal block attached to each semiconductor die and a protrusion from the metal block that extends both laterally and vertically.

14. The method of claim 11, wherein the frame is a lead frame, wherein the lead frame features include a first metal block attached to each semiconductor die and a second metal block separate from the first metal block, wherein a thickness of the second metal block is greater than or equal to a combined thickness of the first metal block and the semiconductor dies.

15. The method of claim 11, wherein the frame is a clip frame, the method further comprising:
forming a lead frame by performing a third etching process during which first regions of an additional metal sheet are not masked and etched to a third depth from a first surface of the additional metal sheet and after the third etching process, performing a fourth etching process during which second regions of the additional metal sheet are not masked and etched to a fourth depth from the first surface of the additional metal sheet, wherein the first regions of the additional metal sheet are not masked during the fourth etching process such that the first regions of the additional metal sheet are etched to a cumulative depth that corresponds to the third depth plus the fourth depth, wherein the first regions and the second regions of the additional metal sheet delimit one or more features of the lead frame; and
attaching the plurality of semiconductor dies to the one or more features of the lead frame; and
singulating both the clip frame and the lead frame with the plurality of semiconductor dies attached thereto into the individual semiconductor packages.

16. A semiconductor package, comprising:
a semiconductor die attached to a lead frame at a first side of the semiconductor die; and
a metal clip attached to a second side of the semiconductor die opposite the first side,
wherein the metal clip has a transition region that extends from a first level above the second side of the semiconductor die to a second level at or below the first side of the semiconductor die,
wherein the transition region comprises a first part that protrudes at the first level from a region of the metal clip attached to the second side of the semiconductor die, and a second part that vertically extends from the first part to the second level and has a curved sidewall.

17. A semiconductor package, comprising:
an insulating material;
a lead frame embedded in the insulating material;
a first semiconductor die embedded in the insulating material and attached to a first metal block of the lead frame at a first side of the first semiconductor die;
a second semiconductor die embedded in the insulating material and attached to the lead frame at a first side of the second semiconductor die, wherein the first metal block has a transition region that laterally extends beyond an edge of the first semiconductor die and vertically extends to a level coplanar with or above a second side of the first semiconductor die opposite the first side; and
a redistribution structure comprising a first part that connects the transition region of the first metal block to a first electrode at a second side of the second semiconductor die opposite the first side.

18. The semiconductor package of claim 17, wherein the lead frame comprises an additional metal block separate from the first metal block, wherein the additional metal block vertically extends to a level coplanar with or above the second side of the first semiconductor die, wherein both the first metal block and the additional metal block are not covered by the insulating material at a first side of the semiconductor package, and wherein the redistribution structure comprises an additional part separate from the first part that connects an electrode at the second side of the first semiconductor die to the additional metal block.

19. The semiconductor package of claim 18, wherein the second metal block has a curved sidewall.

20. The semiconductor package of claim 17, wherein the transition region of the first metal block has a curved sidewall.

21. The semiconductor package of claim 17, wherein the lead frame comprises an additional metal block that vertically extends to a level coplanar with or above the second side of the second semiconductor die, and wherein the redistribution structure comprises an additional part that connects the additional metal block to a second electrode at the second side of the second semiconductor die.

22. The semiconductor package of claim 21, wherein the additional metal block has a curved sidewall.

23. The semiconductor package of claim 17, further comprising:
a gate driver die electrically connected to the first semiconductor die and the second semiconductor die,
wherein the first semiconductor die and the second semiconductor die are each a power transistor die driven by the gate driver die.

24. The semiconductor package of claim 17, wherein the first semiconductor die is a low-side switch device of a power electronics circuit, and wherein the second semiconductor die is a high-side switch device of the power electronics circuit.

25. The semiconductor package of claim 24, wherein the power electronics circuit is a half bridge.

26. The semiconductor package of claim 17, wherein the first metal block is attached to a drain electrode at the first side of the first semiconductor die and the first electrode at the second side of the second semiconductor die is a source electrode, such that the drain electrode of the first semiconductor die is electrically connected to the source electrode of the second semiconductor die by the first metal block with the transition region and the first part of the redistribution structure.
